(19) United States
(12) Patent Application Publication
(10) Pub. No.: US 2025/0063854 A1
(43) Pub. Date: Feb. 20, 2025

(54) APPARATUS FOR TRANSFERRING ELECTRONIC COMPONENTS

(71) Applicant: MARCO Systemanalyse und Entwicklung GmbH, Dachau (DE)

(72) Inventor: Martin REUTER, Dachau (DE)

(21) Appl. No.: 18/806,086

(22) Filed: Aug. 15, 2024

(30) Foreign Application Priority Data
Aug. 18, 2023 (DE) 102023122173.6

(51) Int. Cl. H01L 33/00

(52) U.S. Cl. CPC H01L 33/005

(57) ABSTRACT

An apparatus for transferring electronic components comprises a cross member which can be moved on two rails and on which a slide having a membrane holder is located. A second slide having a needle head is arranged on the cross member.

### CROSS-REFERENCE TO RELATED APPLICATIONS

This application claims priority to German Patent Application No. 102023122173.6, filed on Aug. 18, 2023. The entire disclosure of the above application is incorporated herein by reference.

The present invention relates to an apparatus for transferring electronic components that has a cross member which can be moved on two rails and on which a slide having a membrane holder is attached, wherein the cross member can be moved on the rails in a Y direction by means of a drive and the slide can be moved on the cross member in the X direction by means of a drive.

Such apparatus are known from the prior art (cf., for example, EP 3 271 937 A) and serve to transfer electronic components, for example semiconductor components, from a membrane to a component disposed beneath it. Such semiconductor components, for example MicroLEDs or MiniLEDs, can have very small dimensions, for example in the order of 200×200 μm. Here, a needle head is used to transfer the components and has a needle which can be moved by a drive in the Z direction, i.e. perpendicular to the X direction and perpendicular to the Y direction, and with which a pulse can be applied to a respective component and said component can thereby be transferred from the membrane to the further component.

To release the electronic components from the membrane and to transfer them to the further component, the membrane holder and the needle head are moved over a base surface so that the membrane and the needle head can be travelled into desired dispensing positions.

It is the object of the present invention to provide an apparatus of the initially named kind with which the mounting efficiency can be increased.

This object is satisfied by the features of claim 1 and in particular in that a second slide, at which a needle head is located, is arranged on the cross member, wherein the second slide can be moved on the cross member in the X direction independently of the first slide by means of a second drive. In this way, both the membrane holder and the needle head can in each case be moved independently of one another in the X direction relative to the component to be mounted.

Advantageous embodiments of the invention are described in the description, in the drawing and in the dependent claims.

According to a first advantageous embodiment, the membrane holder can be moveable relative to the cross member in the X direction and/or in the Y direction by means of an additional drive. A fine adjustment can hereby take place and, when passing a certain position, an action above the target location can also be performed out of the movement by activating the auxiliary drive and the drive of the membrane holder in opposite directions.

The same advantages result if the needle head can be moved relative to the cross member in the X direction and/or in the Y direction by means of an additional drive.

Furthermore, it can be advantageous if the membrane holder and/or the needle head can be moved relative to the cross member in a Z direction that is oriented perpendicular to the X direction and perpendicular to the Y direction.

According to a further particularly advantageous embodiment, at least one further cross member can be provided that can be moved on the two rails independently of the first cross member, wherein a further slide having a membrane holder is attached on the further cross member, wherein the further slide can be moved on the further cross member in the X direction by means of a first drive, and wherein a second slide, at which a needle head is located, is arranged on the further cross member and can be moved on the further cross member in the X direction by means of a further drive.

With this embodiment, the production speed can be almost doubled since a further cross member having a membrane holder and a needle head is provided on the same rails.

According to a further advantageous embodiment, in the embodiment described above, the membrane holders and needle heads can be arranged between two cross members in a plan view. The space available between the cross members is hereby utilized in the best possible manner. However, according to a further advantageous embodiment, it is also possible to arrange only one membrane holder and only one needle head between two cross members in a plan view. The overall installation space required is hereby minimized.

According to a further advantageous embodiment, more than two cross members can also be provided that each have a slide having a membrane holder and a slide having a needle head.

The present invention will be described in the following purely by way of example with reference to an advantageous embodiment and to the enclosed drawings. There are shown:

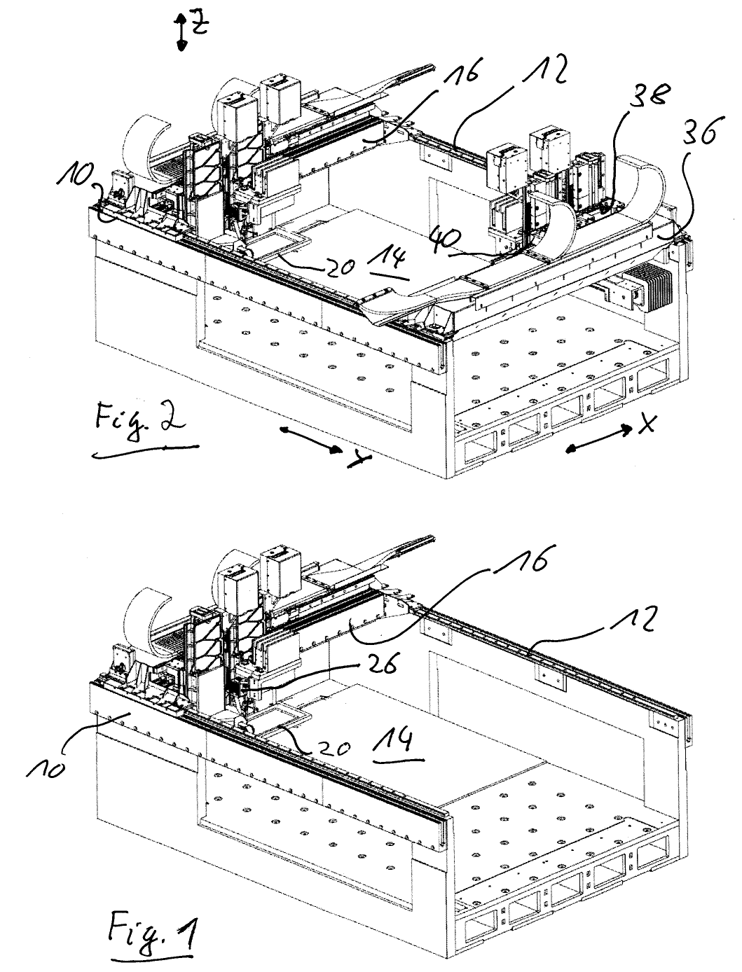

FIG. 1 an apparatus for transferring electronic components comprising two rails and one cross member;

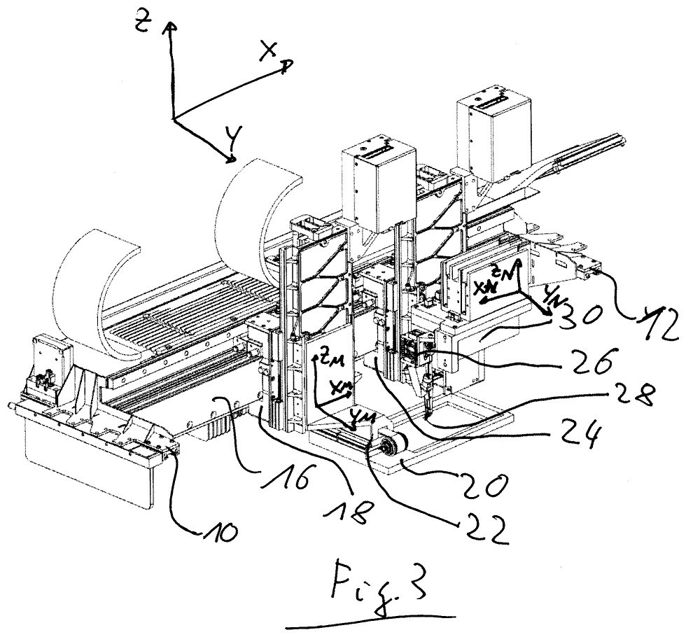

FIG. 2 the apparatus of FIG. 1 comprising two rails and two cross members;

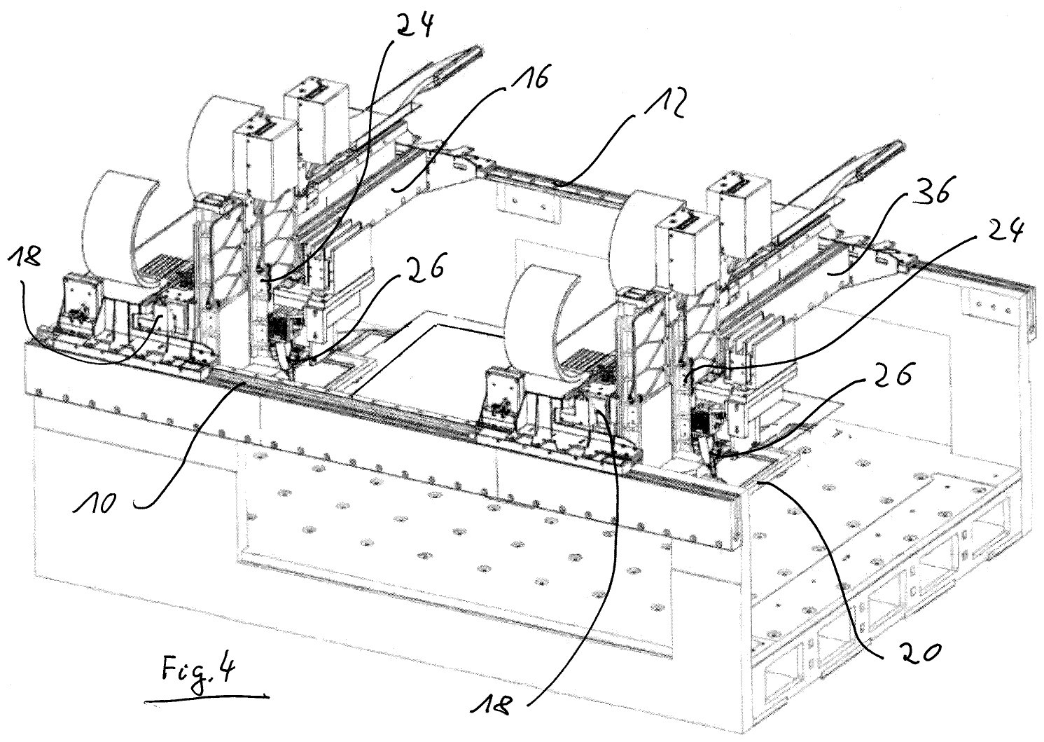

FIG. 3 an enlarged representation of a cross member having a membrane holder and a needle head; and

FIG. 4 a further apparatus for transferring electronic components comprising two rails and two cross members.

FIG. 1 shows an apparatus for transferring electronic components, for example mini LEDs, that comprises two rails 10 and 12 that are provided with linear drives and that are arranged in parallel with one another above a base surface 14. On the two rails 10 and 12, a cross member 16 can be moved in the Y direction by means of the linear drives. Such a cross member is shown enlarged in FIG. 3.

As FIG. 3 illustrates, on the cross member 16, a first slide 18 is located at which a membrane holder 20 is arranged that is oriented in parallel with the base surface 14 and that has a rectangular support frame. By means of an additional drive 22 not shown in detail, the membrane holder 20 can be moved relative to the slide 18 in up to three further directions X_{M}, Y_{M} and Z_{M} oriented at right angles to one another.

A second slide 24, to which a needle head 26 is fastened, is movably arranged on the same cross member 16. With the needle head 26, a needle 28 can be moved in the Z direction (for example by means of a piezo drive) by a small stroke in a pulse-like manner in order to release an electronic component from a membrane located on the membrane holder 20. An additional drive 30 can also be provided by means of which the needle head 26 can be moved in up to three mutually perpendicular directions X_{N}, Y_{N} and Z_{N} relative to the slide 24.

It is understood that it is also possible to move both the membrane holder 20 and the needle head 26 in only one or in only two directions relative to the respective slide 16.

FIG. 2 shows a further embodiment in which, in addition to the embodiment of FIG. 1, a further cross member 36 is provided between the two rails 10 and 12 and can be moved on the two rails 10 and 12 in the Y direction independently of the first cross member 16. A slide 38 having a membrane holder and a further slide 40 having a needle head are in turn located on the second cross member 36. The design of the two slides 38 and 40 as well as of the membrane holder arranged thereat and the needle head arranged thereat is the same as in the embodiment of FIG. 1 and FIG. 3, i.e. the membrane holder and needle head can there also be moved relative to the further slide 36 in up to three directions extending perpendicular to one another relative to the slide.

As FIG. 2 further illustrates, all the membrane holders and needle heads are arranged between the two cross members 16 and 36 in a plan view.

In contrast, in the embodiment of FIG. 4, only a membrane holder and a needle head are arranged between the two cross members 16 and 36 in a plan view, whereby the placement surface of the apparatus is minimized. However, it would also be possible to arrange all the membrane holders and needle heads outside the two cross members in a plan view.

As FIGS. 1 and 2 illustrate, the membrane holder 20 is designed as a rectangular frame. In contrast to round frames, this has the great advantage that a simple alignment of the membrane holder can take place due to the rectangular outer contour. It can be advantageous here if the outer contour of the rectangular frame is selected so that it is inscribed in a circle that corresponds to a round frame that is usually used during production. Such a round frame typically serves to receive and fix the already stretched membrane with the electronic components located thereat. A transfer of this membrane from the round frame to the rectangular frame according to the invention can then take place in a simple manner in that the rectangular frame is adhesively bonded to the membrane located in the round frame and the membrane projecting beyond the rectangular frame is subsequently cut off.

A round frame usually has a diameter of approximately 195 mm during production so that the diagonal of the rectangular frame should be selected in the same order of magnitude or slightly smaller.

1. An apparatus for transferring electronic components, said apparatus comprising a cross member which can be moved on two rails and on which a first slide having a membrane holder is attached, wherein the cross member can be moved on the rails in the Y direction by means of a first drive and the first slide can be moved on the cross member in the X direction by means of a drive, wherein a second slide, at which a needle head is located, is arranged on the cross member, wherein the second slide can be moved on the cross member in the X direction independently of the first slide by means of a second drive.

2. The apparatus according to claim 1,
wherein the membrane holder can be moved relative to the cross member in the X direction and/or in the Y direction by means of an additional drive.

3. The apparatus according to claim 1,
wherein the needle head can be moved relative to the cross member in the X direction and/or in the Y direction by means of an additional drive.

4. The apparatus according to claim 1,
wherein the membrane holder can be moved relative to the cross member in a Z direction, which is perpendicular to the X direction and the Y direction, by means of an additional drive.

5. The apparatus according to claim 1,
wherein the needle head can be moved relative to the cross member in a Z direction, which is perpendicular to the X direction and the Y direction, by means of an additional drive.

6. The apparatus according to claim 1,
wherein at least one further cross member is provided which can be moved on the two rails independently of the first cross member and on which a first slide having a membrane holder is attached, with the slide being movable on the further cross member in the X direction by means of a first drive, and with a further slide, at which a needle head is located, being arranged on the further cross member, with the further slide being movable on the further cross member in the X direction independently of the first slide by means of a further drive.

7. The apparatus according to claim 6,
wherein the membrane holders and needle heads are arranged between two cross members in a plan view.

8. The apparatus according to claim 6,
wherein only one membrane holder and only one needle head are arranged between two cross members in a plan view.

9. The apparatus according to claim 1,
wherein the membrane holder is a rectangular frame.

10. A method of mounting a membrane holder for an apparatus according to claim 1,
wherein a membrane that is located on a round frame and that is provided at one side with electronic components is transferred to a rectangular frame, wherein a rectangular frame is used that is inscribed with its outer contour in the round frame, and wherein the rectangular frame is adhesively bonded to the membrane located in the round frame and the membrane projecting beyond the rectangular frame is subsequently cut off.
